(19) United States
(12) Patent Application Publication
(10) Pub. No.: US 2024/0047696 A1
(43) Pub. Date: Feb. 8, 2024

(54) LAYERED RESIN FILM, COLLECTOR, AND SECONDARY BATTERY

(71) Applicant: TDK CORPORATION, Tokyo (JP)

(72) Inventors: Makoto ENDO, Tokyo (JP); Mingyu CHEN, Tokyo (JP); Yoshihiro KANBAYASHI, Tokyo (JP); Takasi SATOU, Tokyo (JP); Natsumi KOZAI, Tokyo (JP); Yoshihiko TANABE, Tokyo (JP); Syuji TSUKAMOTO, Tokyo (JP); Miyuki YANAGIDA, Tokyo (JP)

(73) Assignee: TDK CORPORATION, Tokyo (JP)

(21) Appl. No.: 18/277,471

(22) PCT Filed: Feb. 18, 2021
(86) PCT No.: PCT/JP2021/006069

§ 371 Date: Aug. 16, 2023

(51) Int. Cl. H01M 4/66; C23C 14/20; C25D 3/38; C25D 5/56

(52) U.S. Cl. CPC H01M 4/667; H01M 4/661; H01M 4/668; C23C 14/205; C25D 3/38; C25D 5/56

(57) ABSTRACT

A laminated resin film includes: a resin layer; and a Cu film having on one surface or both surfaces of the resin layer, in which in the Cu film, an orientation index of a plane is 0.15 or more according to a Lotgering method, a half-width of an X-ray diffraction peak obtained by X-ray diffraction measurement of the plane is 0.3° or less, and Expression (1) is satisfied.

y>3.75x−0.675 Expression (1)

(in Expression (1), Y is the orientation index of the plane in the Cu film according to the Lotgering method, and x is the half-width of the X-ray diffraction peak obtained by the X-ray diffraction measurement of the plane in the Cu film.)

### TECHNICAL FIELD

The present disclosure relates to a laminated resin film, a current collector, and a secondary battery.

### BACKGROUND ART

Lithium secondary batteries are widely utilized as power sources for laptop computers, mobile phones, electric vehicles, and the like.

As a current collector for lithium secondary batteries, there is a laminated resin film in which a metal layer is formed on the surface of a resin layer.

Patent Document 1 discloses a current collector including: an insulating layer; and a conductive layer, in which the conductive layer is mounted on the insulating layer, an electrode active material layer is mounted on the conductive layer, the conductive layer is positioned on at least one surface of the insulating layer, and a metal protective layer is provided on at least one surface of the conductive layer. Patent Document 1 discloses at least one selected from metal conductive materials and carbon-based conductive materials as a material for the conductive layer.

### CITATION LIST

### Patent Document

Patent Document 1

Japanese Unexamined Patent Application, First Publication No. 2019-102429

### SUMMARY OF INVENTION

### Technical Problem

However, when the laminated resin film in which a metal layer is formed on the surface of a resin layer is used as the current collector for lithium secondary batteries, there are concerns of the following (1) to (3).
(1) High electric resistance.
(2) Fracture of the metal layer.
(3) Peeling of the metal layer from the resin layer.

The present disclosure has been made in view of the above-mentioned problems, and an object thereof is to provide a laminated resin film in which electric resistance is low and a metal layer is less likely to fracture or peeled off.

Another object of the present disclosure is to provide a current collector made from the above-mentioned laminated resin film, and a secondary battery which has this current collector and is lightweight and excellent in safety.

### Solution to Problem

In order to achieve the above-mentioned objects, a Cu film as a metal layer was formed on the surface of a resin layer, and intensive studies were conducted with a focus on its crystallinity and orientation.

As a result, it was found that it is sufficient for a Cu film to be formed on the surface of the resin layer, provided that in the Cu film, an orientation index (factor) of a (111) plane according to a Lotgering method and a half-width in the (111) plane in X-ray diffraction measurement are within a specific range.

In other words, the present disclosure relates to the following.

[1] A laminated resin film including: a resin layer; and a Cu film provided on one surface or both surfaces of the resin layer,
in which in the Cu film, an orientation index of a (111) plane is 0.15 or more according to a Lotgering method, a half-width of an X-ray diffraction peak obtained by X-ray diffraction measurement of the (111) plane is 0.3° or less, and Expression (1) is satisfied.

y≥3.75x−0.675 Expression (1)
(in Expression (1), Y is the orientation index of the (111) plane in the Cu film according to the Lotgering method, and x is the half-width of the X-ray diffraction peak obtained by the X-ray diffraction measurement of the (111) plane in the Cu film.)

[2] The laminated resin film according to [1], in which the orientation index of the Cu film is 0.3 to 0.98.

[3] The laminated resin film according to [1] or [2], in which the half-width of the X-ray diffraction peak of the Cu film is 0.08° to 0.26°.

[4] The laminated resin film according to any one of [1] to [3], in which a thickness of the Cu film is 0.3 μm to 2.0 μm.

[5] The laminated resin film according to any one of [1] to [4], in which an underlayer is provided between the resin layer and the Cu film so as to be in contact with the resin layer and the Cu film.

[6] A current collector comprising the laminated resin film according to any one of [1] to [5].

[7] A secondary battery including: a negative electrode; a positive electrode facing the negative electrode; and a separator positioned between the negative electrode and the positive electrode,
in which any one or both of the negative electrode and the positive electrode have the current collector according to [6].

### Advantageous Effects of Invention

A laminated resin film of the present disclosure includes: a resin layer; and a Cu film provided on one surface or both surfaces of the resin layer, in which in the Cu film, an orientation index of a (111) plane is 0.15 or more according to a Lotgering method, a half-width of an X-ray diffraction peak obtained by X-ray diffraction measurement of the (111) plane is 0.3° or less, and Expression (1) is satisfied. Therefore, the laminated resin film of the present disclosure has a low electric resistance, and can prevent the fracture of the Cu film and the peeling of the Cu film from the resin layer.

A current collector of the present disclosure is made from the laminated resin film of the present disclosure. Therefore, the current collector of the present disclosure has a low electric resistance, and can prevent the fracture of the Cu film and the peeling of the Cu film from the resin layer.

In addition, in a secondary battery of the present disclosure, any one or both of a negative electrode and a positive electrode have the current collector of the present disclosure. Accordingly, the secondary battery of the present disclosure is lightweight and excellent in safety.

### BRIEF DESCRIPTION OF DRAWINGS

FIG. 1 is a cross-sectional schematic diagram showing an example of a lithium secondary battery of the present disclosure.

FIG. 2 is a cross-sectional schematic diagram showing an example of a laminated resin film of the present disclosure.

FIG. 3 is a cross-sectional schematic diagram showing another example of the laminated resin film of the present disclosure.

FIG. 4 is a cross-sectional schematic diagram showing still another example of the laminated resin film of the present disclosure.

### DESCRIPTION OF EMBODIMENTS

Hereinafter, the present embodiment will be described in detail with appropriate reference to the drawings. In the drawings used in the following description, characteristic portions may be shown by enlarging them for convenience to facilitate understanding characteristics of the present disclosure, and the dimensional ratios and the like of each of constituent elements may be different from those of actual constituent elements. Materials, dimensions, and the like exemplified in the following description are merely examples, and the present disclosure is not limited thereto and can be implemented with appropriate changes within a range not departing from the scope thereof.

### Lithium Secondary Battery

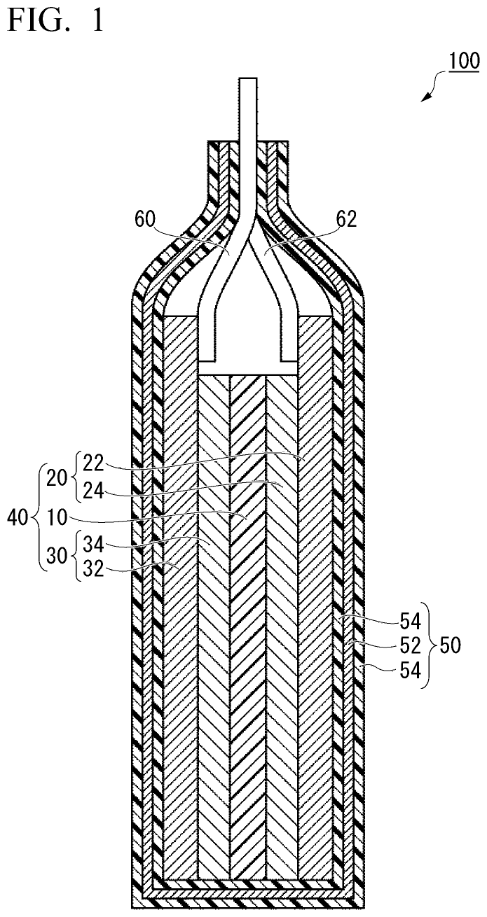

FIG. 1 is a cross-sectional schematic diagram showing an example of a lithium secondary battery of the present disclosure. A lithium secondary battery 100 shown in FIG. 1 includes a power generating part 40, an exterior body 50, and leads 60 and 62. The exterior body 50 accommodates the power generating part 40 in a sealed state. Each of one ends of the pair of the leads 60 and 62 is connected to the power generating part 40, and the other ends extend to the outside of the exterior body 50. In addition, although not shown, an electrolyte solution is accommodated in the exterior body 50 together with the power generating part 40.

### (Power Generating Part)

In the power generating part 40, a positive electrode 20 and a negative electrode are disposed to face each other with a separator 10 interposed therebetween. FIG. 1 shows the case in which one power generating part 40 is accommodated in the exterior body 50, but a plurality of the power generating parts 40 may be laminated and accommodated.

### <Positive Electrode>

The positive electrode 20 has a positive electrode current collector 22 and a positive electrode active material layer 24.

### (Positive Electrode Active Material Layer)

The positive electrode active material layer 24 contains a positive electrode active material, a positive electrode binder, and a positive electrode conductive assistant.

### (Positive Electrode Active Material)

As the positive electrode active material, an electrode active material is used, the electrode active material being capable of absorbing and desorbing lithium ions, deintercalating and intercalating (intercalation) lithium ions, or reversibly advancing doping and dedoping of lithium ions and lithium ion counter anions (for example, PF₆⁻).

Examples of the positive electrode active material include lithium cobaltate (LiCoO₂), lithium nickelate (LiNiO₂), lithium manganese spinel (LiMn₂O₄), a composite metal oxide represented by General Formula: LiNiₓCo_{y}Mn_{z}MₐO₂ (where x+y+z+a=1, 0≤x≤1, 0≤y≤1, 0≤z≤1, 0≤a≤1, and M is one or more elements selected from Al, Mg, Nb, Ti, Cu, Zn, and Cr), a lithium vanadium compound (LiV₂O₅), olivine-type LiMPO₄ (where M indicates one or more elements selected from Co, Ni, Mn, Fe, Mg, Nb, Ti, Al, and Zr, or VO), lithium titanate (Li₄Ti₅O₁₂), and a composite metal oxide represented by LiNiₓCo_{y}Al_{z}O₂ (0.9<x+y+z<1.1).

### (Positive Electrode Binder)

The positive electrode binder binds the positive electrode active materials to each other and also binds the positive electrode active material to the positive electrode current collector 22.

As the positive electrode binder, it is possible to use polyvinylidene fluoride (PVDF), polyethersulfone (PESU), polytetrafluoroethylene (PTFE), a tetrafluoroethylene-hexafluoropropylene copolymer (FEP), a tetrafluoroethylene-perfluoroalkyl vinyl ether copolymer (PFA), an ethylene-tetrafluoroethylene copolymer (ETFE), polychlorotrifluoroethylene (PCTFE), an ethylene-chlorotrifluoroethylene copolymer (ECTFE), polyvinyl fluoride (PVF), and the like, for example.

As the positive electrode binder, the following may also be used: vinylidene fluoride fluororubbers such as vinylidene fluoride-hexafluoropropylene fluororubber (VDF-HFP fluororubber), vinylidene fluoride-hexafluoropropylene-tetrafluoroethylene fluororubber (VDF-HFPTFE fluororubber), vinylidene fluoride-pentafluoropropylene fluororubber (VDF-PFP fluororubber), vinylidene fluoride-pentafluoropropylene-tetrafluoroethylene fluororubber (VDF-PFP-TFE fluororubber), vinylidene fluoride-perfluoromethyl vinyl ether-tetrafluoroethylene fluororubber (VDF-PFMVE-TFE fluororubber), and vinylidene fluoride-chlorotrifluoroethylene fluororubber (VDF-CTFE fluororubber).

As the positive electrode binder, a conductive polymer having electron conductivity and/or a conductive polymer having ion conductivity may be used. Examples of the conductive polymer having electron conductivity include polyacetylene. In this case, the positive electrode binder also exhibits a function as a positive electrode conductive assistant. Therefore, the positive electrode active material layer 24 may not contain the positive electrode conductive assistant. Examples of the conductive polymer having ion conductivity include those obtained by combining polymer compounds such as polyethylene oxide and polypropylene oxide with lithium salts or alkali metal salts mainly composed of lithium.

### (Positive Electrode Conductive Assistant)

The positive electrode conductive assistant improves the conductivity of the positive electrode active material layer 24. A well-known conductive assistant can be used as the positive electrode conductive assistant. Examples of the positive electrode conductive assistant include carbon materials such as graphite and carbon black; fine powders of metals such as copper, nickel, stainless steel, and iron; and conductive oxides such as indium tin oxide (ITO).

### (Positive Electrode Current Collector)

As the positive electrode current collector 22, it is possible to use a metal foil or metal thin plate made of metals such as aluminum, copper, and nickel, for example. The positive electrode current collector 22 may be a laminated resin film having a resin layer (not shown) and having a metal layer made of metals such as aluminum, copper, and nickel on one surface or both surfaces of the resin layer.

### <Negative Electrode>

The negative electrode 30 has a negative electrode current collector 32 and a negative electrode active material layer 34.

(Negative Electrode Active Material Layer)

The negative electrode active material layer 34 contains a negative electrode active material and, if necessary, further contains a negative electrode binder and/or a negative electrode conductive assistant.

### (Negative Electrode Active Material)

The negative electrode active material is a compound capable of absorbing and desorbing lithium ions, and known negative electrode active materials for lithium secondary batteries can be used. As the negative electrode active material, it is possible to use metallic lithium, carbon materials such as graphite (natural graphite, artificial graphite), carbon nanotubes, low graphitizability carbons, high graphitizability carbons, and low-temperature fired carbons; metals that can combine with lithium such as aluminum, silicon, and tin; amorphous compounds mainly including oxides such as SiOₓ (0<x<2) and tin dioxide; particles including lithium titanate (Li₄Ti₅O₁₂) and the like; and the like, for example.

### (Negative Electrode Binder)

As the negative electrode binder, the same binders as those usable as the positive electrode binder can be used. As the negative electrode binder, in addition to those that can be used as the positive electrode binder, for example, one or two or more selected from cellulose, styrene-butadiene rubber, ethylene-propylene rubber, a polyimide resin, a polyamide-imide resin, and an acrylic resin may also be used.

### (Negative Electrode Conductive Assistant)

As the negative electrode conductive assistant, it is possible to use carbon materials such as carbon powders such as carbon black, and carbon nanotubes; fine powders of metals such as copper, nickel, stainless steel, and iron; mixtures of carbon materials and fine powders of metals; conductive oxides such as ITO; and the like, for example.

### (Negative Electrode Current Collector)

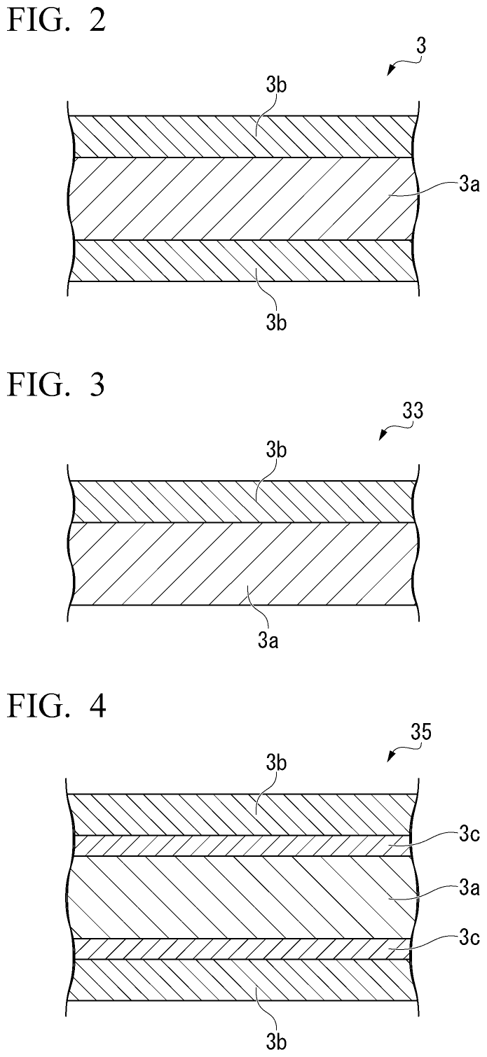

In the lithium secondary battery 100 of the present embodiment, the negative electrode current collector 32 is made from a laminated resin film 3 shown in FIG. 2. As shown in FIG. 2, the laminated resin film 3 has a resin layer 3a, and has Cu films 3b each of which is provided on both surfaces of the resin layer 3a so as to be in contact with the resin layer 3a.

By using the laminated resin film 3 shown in FIG. 2 as the negative electrode current collector 32, the weight of the lithium secondary battery 100 can be reduced as compared to the case of using a current collector made from a metal plate, for example. In addition, by using the laminated resin film 3 as the negative electrode current collector 32, it is possible to prevent the lithium secondary battery 100 from being brought into a high-temperature state because of short-circuiting of conductive portions in the lithium secondary battery 100 via the negative electrode current collector 32.

In the laminated resin film 3 shown in FIG. 2, the Cu films 3b each of which are provided on both surfaces of the resin layer 3a may be the same as each other, or may be those in which one or more constitutions selected from an orientation index of a (111) plane according to a Lotgering method, a half-width of an X-ray diffraction peak obtained by X-ray diffraction measurement of the (111) plane, and a thickness are different.

As shown in FIG. 2, the laminated resin film 3 has the resin layer 3a, and has the Cu films 3b each of which is provided on both surfaces of the resin layer 3a. In the lithium secondary battery 100 of the present embodiment, only one power generating part 40 is accommodated in the exterior body 50. Therefore, instead of the laminated resin film 3 shown in FIG. 2, as shown in FIG. 3, a laminated resin film 33 in which a Cu film 3b is provided on only one surface of the resin layer 3a (the surface on the side of the negative electrode active material layer 34 in the lithium secondary battery 100 of the present embodiment) so as to be in contact with the resin layer 3a may be used.

When a plurality of the power generating parts 40 are laminated and accommodated in the exterior body 50, as the negative electrode current collector 32, it is preferable to use the laminated resin film 3 in which the Cu films 3b are provided on both surfaces of the resin layer 3a. In this case, by providing the negative electrode active material layers 34 on both surfaces of the laminated resin film 3, one laminated resin film 3 can serve as the negative electrode current collector 32 of two negative electrodes 30.

Examples of the resin layer 3a forming the laminated resin films 3 and 33 include film-like ones made of polyethylene terephthalate (PET), polyethylene (PE), polypropylene (PP), polyamide, polyimide, polystyrene, polyvinyl chloride, an acrylonitrile-butadiene-styrene copolymer, polybutylene terephthalate, poly-p-phenylene terephthalamide, polypropylene ethylene, polyformaldehyde, an epoxy resin, a phenolic resin, polytetrafluoroethylene, polyvinylidene fluoride, silicone rubber, polycarbonate, and the like. Among these, it is preferable to use a film made of PET because it has excellent chemical resistance, stretchability, and tensile strength.

The thickness of the resin layer 3a forming the laminated resin films 3 and 33 can be appropriately determined according to the usage of the lithium secondary battery 100. The thickness of the resin layer 3a is preferably 3 μm to 12 μm, and is more preferably 3 μm to 6 μm, for example. When the thickness of the resin layer 3a is 3 μm or more, deformation of the laminated resin films 3 and 33 can be inhibited, and fracture of the Cu film 3b and peeling of the Cu film 3b from the resin layer 3a can further be prevented. In addition, when the thickness of the resin layer 3a is 12 μm or less, this is preferable because then the laminated resin films 3 and 33 do not hinder the miniaturization of the lithium secondary battery 100.

In the Cu film 3b forming the laminated resin films 3 and 33, the orientation index of the (111) plane is 0.15 or more according to the Lotgering method, the half-width of the X-ray diffraction peak obtained by the X-ray diffraction measurement of the (111) plane is 0.3° or less, and Expression (1) is satisfied.

y>3.75x−0.675 Expression (1)
(in Expression (1), Y is the orientation index of the (111) plane in the Cu film 3b according to the Lotgering method, and x is the half-width of the X-ray diffraction peak obtained by the X-ray diffraction measurement of the (111) plane in the Cu film 3b.)

The orientation index (factor) of the (111) plane of the Cu film 3b according to the Lotgering method is a numerical value that serves as an index of the orientation of the Cu film 3b. The maximum value of the orientation index according to the Lotgering method is 1. An orientation index of 1 indicates complete orientation, and an orientation index of 0 indicates no orientation. The orientation index according to the Lotgering method can be calculated by the method described below.

The orientation index (factor (F)) of the (111) plane of the Cu film 3b according to the Lotgering method is calculated by Formula (2) using the intensity of the X-ray diffraction peak obtained by the X-ray diffraction measurement of the Cu film.

F=(ρ−ρ0)/(1−ρ0) Formula (2)
(in Formula (2), ρ0 is a value obtained by Formula (3), and ρ is a value obtained by Formula (4).)

ρ0=ΣI0(111)/ΣI0(hkl) Formula (3)
(in Formula (3), I0(111) represents the intensity of the X-ray diffraction peak of the (111) plane obtained by the X-ray diffraction measurement of a non-oriented Cu powder, and I0(hkl) indicates the intensity of all diffraction peaks obtained by the X-ray diffraction measurement of a non-oriented Cu film.)

In the present embodiment, the non-oriented Cu film means that the intensity pattern of the X-ray diffraction peak is close to the intensity pattern of the X-ray diffraction peak of a copper standard sample listed in the Joint Committee on Powder Diffraction Standards (JCPDS).

ρ=ΣI(111)/ΣI(hkl) Formula (4)
(in Formula (4), I(111) represents the intensity of the X-ray diffraction peak of the (111) plane obtained by the X-ray diffraction measurement of the Cu film forming the laminated resin film of the present embodiment, and I(hkl) represents the intensity of all diffraction peaks obtained by the X-ray diffraction measurement of the Cu film forming the laminated resin film of the present embodiment.)

In the laminated resin films 3 and 33 of the present embodiment, the higher the orientation index of the (111) plane in the Cu film 3b according to the Lotgering method, the more the ductility of the Cu film is improved, which is preferable because then the Cu film 3b is less likely to be peeled off from the resin layer 3a. The orientation index of the Cu film 3b is 0.15 or more, preferably 0.3 or more, and more preferably 0.35 or more. In addition, the orientation index of the Cu film 3b is preferably 0.98 or less, and more preferably 0.75 or less. When the orientation index of the Cu film 3b is 0.98 or less, the Cu film 3b is less likely to be oxidized, which makes it possible to inhibit an increase of the electric resistance of the Cu film 3b.

In the laminated resin films 3 and 33 of the present embodiment, the half-width of the X-ray diffraction peak obtained by the X-ray diffraction measurement of the (111) plane in the Cu film 3b is a numerical value that serves as an index of the crystallite size of the Cu film 3b. Specifically, the smaller the above-mentioned half-width of the X-ray diffraction peak, the larger the crystallite size of the Cu film 3b.

In the laminated resin film 3 of the present embodiment, the smaller the half-width of the X-ray diffraction peak obtained by the X-ray diffraction measurement of the (111) plane in the Cu film 3b, the larger the fracture elongation of the Cu film 3b, which is preferable because then fracture is less likely to occur, and electric resistance is low. The half-width of the X-ray diffraction peak of the (111) plane in the Cu film 3b is 0.3° or less, preferably 0.26° or less, and more preferably 0.22° or less. In addition, the half-width of the X-ray diffraction peak of the (111) plane in the Cu film 3b is preferably 0.08° or more. When the half-width of the X-ray diffraction peak of the (111) plane in the Cu film 3b is 0.08° or more, the Cu film 3b can be efficiently and easily formed.

The Cu film 3b in the laminated resin films 3 and 33 of the present embodiment satisfies Expression (1). Therefore, the laminated resin film 3 of the present embodiment has a low electric resistance, and can prevent the fracture of the Cu film 3b and the peeling of the Cu film 3b from the resin layer 3a.

When the Cu film 3b does not satisfy Expression (1), the above-mentioned effects cannot be sufficiently obtained even when the orientation index of the (111) plane according to the Lotgering method is 0.15 or more, and when the half-width of the X-ray diffraction peak obtained by the X-ray diffraction measurement of the (111) plane is 0.3° or less.

The thickness of the Cu film 3b in the laminated resin films 3 and 33 of the present embodiment is preferably 0.3 μm to 2.0 μm, and is more preferably 0.5 μm to 1.0 μm. When the thickness of the Cu film 3b is 0.3 μm or more, the laminated resin films 3 and 33 having even lower electric resistance are obtained. In addition, when the thickness of the Cu film 3b is 0.5 μm or more, fracture of the Cu film 3b and peeling of the Cu film 3b from the resin layer 3a can further be prevented. Furthermore, when the thickness of the Cu film 3b is 2.0 μm or less, by using the laminated resin films 3 and 33 as the negative electrode current collector 32, the weight of the lithium secondary battery 100 can be further reduced.

### “Method for Manufacturing Laminated Resin Film”

Next, a method for manufacturing the laminated resin films 3 and 33 will be described with reference to an example.

First, the resin layer 3a having a predetermined thickness is formed by a known method using a predetermined resin. A commercially available resin film may be used as the resin layer 3a.

Next, the Cu film 3b is formed on one surface or both surfaces of the resin layer 3a so as to be in contact with the resin layer 3a. The orientation index of the (111) plane of the Cu film 3b according to the Lotgering method, and the half-width of the X-ray diffraction peak obtained by the X-ray diffraction measurement of the (111) plane can be controlled by a film formation method and the thickness of the Cu film 3b.

In the present embodiment, the Cu film 3b is preferably formed by performing, in the following order, the following steps: a step of forming a Cu seed layer on one surface or both surfaces of the resin layer 3a; and a step of forming a Cu plated layer on the Cu seed layer by an electrolytic plating method.

Examples of the step of forming the Cu seed layer include a method in which a Cu seed layer made from a Cu film is formed on one surface or both surfaces of the resin layer 3a by film formation methods such as an electroless plating method, a sputtering method, a vapor deposition method, and a chemical vapor deposition method (CVD method). In the step of forming the Cu seed layer, among the above-mentioned film formation methods, it is preferable to form the Cu seed layer by using any method selected from the electroless plating method, the sputtering method, and the vapor deposition method, and it is particularly preferable to use the sputtering method. This is because, by performing the step of forming the Cu plated layer, this makes it possible to obtain a Cu seed layer that facilitates obtaining of the Cu film 3b in which the orientation index of the (111) plane according to the Lotgering method is 0.15 or more, and the half-width of the X-ray diffraction peak obtained by the X-ray diffraction measurement of the (111) plane is 0.3° or less.

When the sputtering method is used in the step of forming the Cu seed layer, it is preferable to form the Cu seed layer in an atmosphere containing argon. The atmosphere containing argon may be an atmosphere consisting only of argon gas, or may be an atmosphere of a mixed gas of argon gas and hydrogen gas, but is preferably the atmosphere consisting only of argon gas. This is because it is possible to obtain a Cu seed layer that facilitates the formation of the Cu film 3b in which the orientation index of the (111) plane according to the Lotgering method is 0.15 or more.

In the step of forming the Cu seed layer, it is preferable to form a Cu seed layer made from a Cu film having a thickness of 10 to 300 nm. When the thickness of the Cu seed layer is 300 nm or less, this is preferable because, by performing the step of forming the Cu plated layer, this further facilitates obtaining of the Cu film 3b in which the orientation index of the (111) plane according to the Lotgering method is 0.15 or more, and the half-width of the X-ray diffraction peak obtained by the X-ray diffraction measurement of the (111) plane is 0.3° or less. When the thickness of the Cu seed layer is 10 nm or more, this is preferable because, in the step of forming the Cu plated layer, holes (pinholes) reaching the resin layer 3a can be inhibited from being generated when the Cu seed layer is dissolved in a plating liquid. By performing the step of forming the Cu plated layer, the Cu seed layer is integrated with the Cu plated layer to become a part of the Cu film.

Examples of the step of forming the Cu plated layer include a method in which the Cu film 3b having a thickness of 0.3 μm to 2.0 μm is formed on the Cu seed layer formed on one surface or both surfaces of the resin layer 3a by the electrolytic plating method. In the electrolytic plating method, a plating liquid having a known composition can be used. Plating conditions such as a plating temperature and a plating time in the electrolytic plating method can be appropriately determined according to the thickness of the Cu film 3b of the laminated resin films 3 and 33, and the like.

The current density in the electrolytic plating method can be 1.5 to 5.0 A/dm², for example. By changing the current density in the electrolytic plating method, it is possible to control the orientation index of the (111) plane according to the Lotgering method.

A method for forming the Cu film 3b on one surface or both surfaces of the resin layer 3a is not limited to the method of performing the step of forming the Cu seed layer and the step of forming the Cu plated layer by the electrolytic plating method. For example, the Cu film 3b may be formed on one surface or both surfaces of the resin layer 3a by using only one film formation method selected from the electroless plating method, the sputtering method, the vapor deposition method, and the chemical vapor deposition method (CVD method). In this case, the resin layer 3a can be efficiently formed with fewer manufacturing steps as compared to the case in which the step of forming the Cu seed layer and the step of forming the Cu plated layer are performed.

When the Cu films 3b are formed on both surfaces of the resin layer 3a, the Cu films 3b may be formed on both surfaces of the resin layer 3a at the same time, or, alternatively, the Cu film 3b may be formed on one surface, and thereafter the Cu film 3b may be formed on the opposite surface. When the Cu films 3b are formed on both surfaces of the resin layer 3a, it is preferable to form the Cu films 3b on both surfaces of the resin layer 3a at the same time because then the laminated resin film 3 can be manufactured efficiently.

In the lithium secondary battery 100 of the present embodiment, instead of the laminated resin film 3, as shown in FIG. 4, a laminated resin film 35 in which an underlayer 3c and a Cu film 3b are provided in this order on each of both surfaces of a resin layer 3a may be used.

As shown in FIG. 4, the underlayer 3c is provided between the resin layer 3a and the Cu film 3b so as to be in contact with the resin layer 3a and the Cu film 3b. By providing the underlayer 3c, the adhesiveness between the resin layer 3a and the Cu film 3b can be enhanced. When the Cu film 3b is provided on both surfaces of the resin layer 3a, the underlayer 3c may be provided on each of both surfaces of the resin layer 3a as shown in FIG. 4, or may be provided on only one surface of the resin layer 3a.

The underlayer 3c is preferably a metal layer containing at least one element selected from the group consisting of Cr, Ti, and Ni. When the laminated resin film 35 is used as the negative electrode current collector 32, the underlayer 3c may be a metal layer containing at least one element selected from the group consisting of Cr, Ti, Ni, Ta, Zn, Nb, and Cu, but is preferably a metal layer containing Ni, and is more preferably a metal layer consisting of an alloy of Ni and Cr.

The laminated resin film 35 shown in FIG. 4 can be manufactured by the method described below, for example. The resin layer 3a is formed in the same manner as in manufacturing of the laminated resin film 3 shown in FIG. 2. Subsequently, the underlayer 3c is formed on both surfaces of the resin layer 3a so as to be in contact with the resin layer 3a by the film formation methods such as the sputtering method and the vapor deposition method. Thereafter, the Cu films 3b are formed on the underlayers 3c provided on both surfaces of the resin layer 3a in the same manner as in the case of forming the Cu films 3b of the laminated resin film 3 shown in FIG. 2. Through the steps described above, the laminated resin film 35 shown in FIG. 4 is obtained.

### <Separator>

As the separator 10, a known separator such as one having electrical insulation and consisting of a porous structure can be used. Specific examples thereof include a single layer body or a laminated body of films made of polyolefin resins such as polyethylene and polypropylene; a stretched film of a mixture made of a plurality of types of polyolefin resins; and a fibrous nonwoven fabric made of at least one constituent material selected from the group consisting of cellulose, polyester, and polypropylene.

### (Electrolyte Solution)

The power generating part 40 is impregnated with the electrolyte solution. As the electrolyte solution, an electrolytic solution or a non-aqueous electrolytic solution can be used. When the non-aqueous electrolytic solution is used as the electrolyte solution, this is preferable because then a tolerable voltage during charging can be increased as compared to the case of using the aqueous electrolytic solution.

The non-aqueous electrolytic solution is obtained by dissolving an electrolyte in a non-aqueous solvent. As the non-aqueous solvent, cyclic carbonates and chain carbonates can be used, for example.

As the cyclic carbonate, one that can solvate the electrolyte is used. Examples of the cyclic carbonates include ethylene carbonate, propylene carbonate, and butylene carbonate.

As the chain carbonate, one that lowers the viscosity of the cyclic carbonate is used. Examples of the chain carbonates include diethyl carbonate, dimethyl carbonate, and ethyl methyl carbonate.

As the non-aqueous solvent, methyl acetate, ethyl acetate, methyl propionate, ethyl propionate, γ-butyrolactone, 1,2-dimethoxyethane, 1,2-diethoxyethane, and the like may also be used in addition to the cyclic carbonates and the chain carbonates.

Examples of electrolytes contained in the non-aqueous electrolytic solution include lithium salts such as LiPF₆, LiClO₄, LiBF₄, LiCF₃SO₃, LiCF₃CF₂SO₃, LiC(CF₃SO₂)₃, LiN(CF₃SO₂)₂, LiN(CF₃CF₂SO₂)₂, LiN(CF₃SO₂)(C₄F₉SO₂), LiN(CF₃CF₂CO)₂, and LiBOB. For these lithium salts, one type may be used alone, or two or more types may be used in combination. From the viewpoint of a degree of ionization, the electrolyte preferably includes LiPF₆.

As the non-aqueous electrolytic solution, an ionic liquid may be used, for example. The ionic liquid is a salt (room temperature molten salt) in the liquid state even at a low temperature of, for example, lower than 100° C., and is a combination of cations and anions. The ionic liquid has a strong electrostatic interaction and is nonvolatile and nonflammable. Therefore, the lithium secondary battery 100 using the ionic liquid as the non-aqueous electrolytic solution is excellent in safety.

As a cation component and an anion component of the ionic liquid, known ones can be used.

### (Lead)

The leads 60 and 62 are formed of a conductive material such as aluminum. As shown in FIG. 1, the lead 60 is electrically connected to the negative electrode current collector 32 of the negative electrode 30. The lead 62 is electrically connected to the positive electrode current collector 22 of the positive electrode 20.

### (Exterior Body)

The exterior body 50 seals the power generating part 40 and the electrolyte solution inside. The exterior body 50 is not particularly limited as long as it can restrain the leakage of the electrolyte solution to an external device and the invasion of water or the like from an external device into the inside.

As the exterior body 50, it is possible to use one made from a metal laminate film in which both surfaces of a metal foil 52 are coated with a polymer film 54, for example, as shown in FIG. 1.

As the metal foil 52, an aluminum foil can be used, for example. As the polymer film 54 on the outer side, it is preferable to use one made of a polymer having a high melting point. For example, a film made of polyethylene terephthalate (PET), polyamide, or the like can be used. As the polymer film 54 on the inner side, it is possible to use a film made of polyethylene (PE), polypropylene (PP), or the like, for example.

### Method for Manufacturing Lithium Secondary Battery

Next, a method for manufacturing the lithium secondary battery 100 shown in FIG. 1 will be described in detail with reference to an example.

To manufacture the lithium secondary battery 100 of the present embodiment, first, the positive electrode 20 and the negative electrode 30 are produced.

As a method for manufacturing the positive electrode 20, for example, it is possible to use a method in which a paint containing the positive electrode active material is applied onto the positive electrode current collector 22 and dried.

As the paint containing the positive electrode active material, it is possible to use one containing the positive electrode active material, the positive electrode binder, the positive electrode conductive assistant, and a solvent. As the solvent, water, N-methyl-2-pyrrolidone, or the like can be used. The paint containing the positive electrode active material can be produced by mixing each component used for the paint containing the positive electrode active material by a known method. A method of mixing each component used for the paint containing the positive electrode active material is not particularly limited, and the order of mixing is also not particularly limited.

A method of applying the paint containing the positive electrode active material to the positive electrode current collector 22 is not particularly limited, and a method that is usually employed when manufacturing the positive electrode 20 can be used. Examples of the method of applying the paint containing the positive electrode active material include a slit die coating method and a doctor blade method.

A method in which a coating film is formed by applying the paint containing the positive electrode active material and thereafter drying is performed by removing the solvent in the coating film is not particularly limited. For example, it is possible to use a method in which the positive electrode current collector 22 to which the paint containing the positive electrode active material is applied is dried in an atmosphere of 80° C. to 150° C. Thereby, the positive electrode 20 in which the positive electrode active material layer 24 is formed on the positive electrode current collector 22 is obtained.

To manufacture the negative electrode 30, first, the laminated resin film 3 shown in FIG. 2 is prepared as the negative electrode current collector 32. Thereafter, a paint containing the negative electrode active material is applied onto the laminated resin film 3 and dried. The negative electrode active material layer 34 can be formed in the same manner as the positive electrode active material layer 24 by using the paint containing the negative electrode active material instead of the paint containing the positive electrode active material.

As the paint containing the negative electrode active material, it is possible to use one containing the negative electrode active material, the negative electrode binder, the negative electrode conductive assistant, and a solvent. As the solvent, water, N-methyl-2-pyrrolidone, or the like can be used. The paint containing the negative electrode active material can be produced by mixing each component used for the paint containing the negative electrode active material by a known method. A method of mixing each component used for the paint containing the negative electrode active material is not particularly limited, and the order of mixing is also not particularly limited.

Next, as shown in FIG. 1, the positive electrode 20 and the negative electrode 30 are laminated with the separator 10 interposed therebetween to form the power generating part 40. Thereafter, the power generating part 40 is put into the previously produced pouch-shaped exterior body 50 together with the electrolyte solution, and the entrance of the exterior body 50 is sealed. Through the steps described above, the lithium secondary battery 100 shown in FIG. 1 is obtained.

In the lithium secondary battery 100 of the present embodiment, the negative electrode current collector 32 is made from the laminated resin film 3 shown in FIG. 2. The laminated resin film shown in FIG. 2 has the resin layer 3a, and the Cu films 3b provided on both surfaces of the resin layer 3a, in which in the Cu film 3b, the orientation index of the (111) plane is 0.15 or more according to the Lotgering method, the half-width of the X-ray diffraction peak obtained by the X-ray diffraction measurement of the (111) plane is 0.3° or less, and Expression (1) is satisfied. Therefore, the negative electrode current collector 32 made from the laminated resin film 3 shown in FIG. 2 has a low electric resistance, and can prevent the fracture of the Cu film 3b of the laminated resin film 3 and the peeling of the Cu film 3b from the resin layer 3a. Accordingly, the lithium secondary battery 100 of the present embodiment is lightweight and excellent in safety.

Although the embodiments of the present disclosure have been described in detail with reference to the drawings, each of the configurations, combinations thereof, and the like in each of the embodiments is an example, and additions, omissions, replacements, and other changes can be made within a range not deviating from the gist of the present disclosure.

For example, in the lithium secondary battery 100 of the above-mentioned embodiment, the case in which the laminated resin film 3 shown in FIG. 2 is provided as the negative electrode current collector 32 has been described as the example. However, in the lithium secondary battery of the present disclosure, it is sufficient for any one or both of the negative electrode and the positive electrode to have the current collector made from the laminated resin film of the present disclosure. In other words, the laminated resin film of the present disclosure may be provided as the positive electrode current collector in the lithium secondary battery of the present disclosure, or the laminated resin film of the present disclosure may be provided as the positive electrode current collector and the negative electrode current collector.

When the laminated resin film 35 shown in FIG. 4 is provided as the positive electrode current collector 22, the underlayer 3c may be a metal layer containing at least one element selected from the group consisting of Cr, Ti, Ni, Ta, Zn, Nb, Cu, and Al.

### EXAMPLES

### Examples 1 to 21 and Comparative Examples 1 and 2

A resin layer 3a (trade name: DIAFOIL, manufactured by Mitsubishi Chemical Corporation) made of polyethylene terephthalate (PET) and having a thickness of 4.5 μm was prepared. Subsequently, using the Cu film formation method shown in Table 1, Cu films 3b having the thicknesses shown in Table 2 were formed on both surfaces of the resin layer 3a at the same time to obtain the laminated resin film 3 shown in FIG. 2.

TABLE 1

| | | Thickness of | Film formation | Plating current |
|---|---|---|---|---|
| | | Cu seed layer | atmosphere of | density |
| | Cu film formation method | (μm) | Cu seed layer | (A/dm²) |
| Comparative | 1st: sputtering, | 0.2 | Ar + H² | 4 |
| Example 1 | 2nd: electrolytic plating | | | |
| Comparative | 1st: sputtering, | 0.25 | Ar + H² | 2.5 |
| Example 2 | 2nd: electrolytic plating | | | |
| Example 1 | 1st: sputtering, | 0.1 | Ar + H² | 4.0 |
| | 2nd: electrolytic plating | | | |
| Example 2 | 1st: sputtering, | 0.1 | Ar | 1.5 |
| | 2nd: electrolytic plating | | | |
| Example 3 | Sputtering | 0.5 | Ar | — |
| Example 4 | 1st: sputtering, | 0.05 | Ar | 1.5 |
| | 2nd: electrolytic plating | | | |
| Example 5 | 1st: sputtering, | 0.05 | Ar | 2.5 |
| | 2nd: electrolytic plating | | | |
| Example 6 | 1st: sputtering, | 0.05 | Ar + H² | 2 |
| | 2nd: electrolytic plating | | | |
| Example 7 | 1st: sputtering, | 0.05 | Ar | 2 |
| | 2nd: electrolytic plating | | | |
| Example 8 | 1st: sputtering, | 0.03 | Ar | 2.5 |
| | 2nd: electrolytic plating | | | |
| Example 9 | 1st: sputtering, | 0.05 | Ar | 3 |
| | 2nd: electrolytic plating | | | |
| Example 10 | 1st: sputtering, | 0.05 | Ar | 4 |
| | 2nd: electrolytic plating | | | |
| Example 11 | Sputtering | 0.5 | Ar + H² | — |
| Example 12 | 1st: sputtering, | 0.15 | Ar | 2 |
| | 2nd: electrolytic plating | | | |
| Example 13 | 1st: sputtering, | 0.03 | Ar | 2 |
| | 2nd: electrolytic plating | | | |
| Example 14 | 1st: sputtering, | 0.1 | Ar | 3.5 |
| | 2nd: electrolytic plating | | | |
| Example 15 | 1st: sputtering, | 0.05 | Ar + H² | 3 |
| | 2nd: electrolytic plating | | | |
| Example 16 | 1st: sputtering, | 0.05 | Ar + H² | 5 |
| | 2nd: electrolytic plating | | | |
| Example 17 | 1st: sputtering, | 0.15 | Ar + H² | 5 |
| | 2nd: electrolytic plating | | | |
| Example 18 | 1st: sputtering, | 0.05 | Ar | 3 |
| | 2nd: electrolytic plating | | | |
| Example 19 | 1st: sputtering, | 0.05 | Ar | 4.5 |
| | 2nd: electrolytic plating | | | |
| Example 20 | 1st: sputtering, | 0.05 | Ar | 4.5 |
| | 2nd: electrolytic plating | | | |
| Example 21 | 1st: sputtering, | 0.03 | Ar | 5 |
| | 2nd: electrolytic plating | | | |

TABLE 2

| | | Half-width | Orientation | Whether | | | |
|---|---|---|---|---|---|---|---|
| | Thickness | of (111) | index of | Expression | Fracture | | Calendering |
| | of Cu film | plane | (111) plane | (1) is | elongation | Resistance | resistance |
| | (μm) | (°) | (ρ) | satisfied | (%) | (μΩ · cm) | treatment |
| Comparative | 0.5 | 0.08 | 0.12 | O | 25 | 1.7 | NG |
| Example 1 | | | | | | | |
| Comparative | 0.5 | 0.20 | 0.12 | O | 18 | 1.9 | NG |
| Example 2 | | | | | | | |
| Example 1 | 0.5 | 0.10 | 0.20 | O | 25 | 1.7 | No peeling |
| Example 2 | 0.5 | 0.30 | 0.50 | O | 4.5 | 3.0 | No peeling |
| Example 3 | 0.5 | 0.28 | 0.65 | O | 4.5 | 2.7 | No peeling |
| Example 4 | 0.5 | 0.28 | 0.83 | O | 4.5 | 2.8 | No peeling |
| Example 5 | 0.5 | 0.18 | 0.92 | O | 25 | 2.8 | No peeling |
| Example 6 | 0.5 | 0.22 | 0.30 | O | 17 | 2.0 | No peeling |
| Example 7 | 0.5 | 0.24 | 0.66 | O | 10 | 2.4 | No peeling |
| Example 8 | 0.5 | 0.22 | 0.85 | O | 18 | 2.0 | No peeling |
| Example 9 | 0.5 | 0.14 | 0.80 | O | 25 | 1.7 | No peeling |
| Example 10 | 0.5 | 0.10 | 0.82 | O | 30 | 1.7 | No peeling |
| Example 11 | 0.5 | 0.22 | 0.40 | O | 18 | 2.0 | Extremely |
| | | | | | | | good |
| Example 12 | 0.5 | 0.20 | 0.55 | O | 20 | 2.0 | Extremely |
| | | | | | | | good |
| Example 13 | 0.5 | 0.19 | 0.74 | O | 18 | 1.8 | Extremely |
| | | | | | | | good |
| Example 14 | 0.5 | 0.15 | 0.55 | O | 25 | 1.7 | Extremely |
| | | | | | | | good |
| Example 15 | 0.5 | 0.15 | 0.15 | O | 24 | 1.9 | No peeling |
| Example 16 | 0.5 | 0.07 | 0.55 | O | 6 | 1.7 | No peeling |
| Example 17 | 0.5 | 0.07 | 0.38 | O | 10 | 1.7 | No peeling |
| Example 18 | 0.2 | 0.18 | 0.50 | O | 35 | 2.6 | No peeling |
| Example 19 | 2.5 | 0.12 | 0.60 | O | 15 | 1.8 | No peeling |
| Example 20 | 0.5 | 0.18 | 0.98 | O | 25 | 2.9 | No peeling |
| Example 21 | 0.5 | 0.18 | 0.99 | O | 25 | 3.0 | No peeling |

The term “1^{st}” written in the Cu film formation method shown in Table 1 is a film formation method in a step of forming a Cu seed layer. Table 1 shows the thickness of a Cu seed layer and a film formation atmosphere when the Cu seed layer was formed.

The term “2^{st}” written in the Cu film formation method shown in Table 1 is a film formation method in a step of forming a Cu plated layer performed after “1^{st}”. Table 1 shows the plating current density in the step of forming the Cu plated layer.

For the laminated resin film 3 thus obtained, X-ray diffraction measurement of the Cu films 3b was performed using an X-ray diffraction (XRD) machine (trade name: X'Pert PRO MRD, manufactured by PANalytical). Based on the results, the orientation index of the (111) plane of the Cu film 3b according to the Lotgering method, and the half-width of the X-ray diffraction peak obtained by the X-ray diffraction measurement of the (111) plane were respectively calculated according to the above-mentioned methods. Table 2 shows the results.

In addition, whether or not the Cu film 3b satisfied Expression (1) above was examined using the calculated orientation index of the (111) plane according to the Lotgering method, and the calculated half-width of the X-ray diffraction peak obtained by the X-ray diffraction measurement of the (111) plane. Table 2 shows the results. In Table 2, the case of satisfying Expression (1) above is indicated as “O”, and the case of not satisfying Expression (1) above is indicated as “X”.

In addition, the fracture elongation and the resistance of the laminated resin film 3 were respectively measured by the methods described below, and a calendering resistance treatment was evaluated.

### “Fracture Elongation”

Using a desktop force tester (trade name: FTN1-13A, manufactured by Aikoh Engineering Co., Ltd.), a tensile test was carried out to measure the elongation when the sample fractured.

The fracture elongation was calculated by the following formula.

Fracture elongation (%)={(ΔL/L)−1}×100
(in the formula, L is the sample length before the tensile test, and ΔL is the sample length when fractured.)

### “Resistance”

Using a low resistivity meter (trade name: Loresta-GX MCP-T700, manufactured by Nittoseiko Analytech Co., Ltd.), the surface resistance value of the laminated resin film 3 was measured. By multiplying the obtained surface resistance value of the laminated resin film 3 by the film thickness of the Cu film, the volume resistance value of the laminated resin film 3 was calculated and used as the resistance.

### “Calendering Resistance Treatment”

A primer paint composed of carbon black, carboxymethyl cellulose, styrene-butadiene rubber, and water was applied onto the Cu film 3b of the laminated resin film 3 to form a primer layer.

In addition, an active material paint composed of graphite, carboxymethyl cellulose, styrene-butadiene rubber, and water was applied onto the primer layer of the laminated resin film 3 and dried at 60° C. for 3 hours to form an active material layer.

Thereafter, the laminated resin film 3 on which the active material layer was formed was subjected to a calendering treatment of passing the laminated resin film 3 between rotating rolls under a linear pressure of 600 kg/cm.

Regarding the laminated resin film 3 after passing between the rolls, using a scanning electron microscope (Hitachi High-Tech Corporation S-4800), whether or not the Cu films 3b on both surfaces were peeled off from the resin layer 3 was observed under the following conditions, and evaluation was performed according to the following criteria.

### (Observation Conditions)

Microscopic observation magnification: 5,000 times
The number of observed visual field: 30 visual fields

### (Evaluation Criteria)

“No peeling”: no peeling at a linear pressure of 1.0 times (600 kg/cm) (30 visual fields were observed, and no peeled sites were recognized)
“Extremely good”: no peeling at a linear pressure of 1.5 times (900 kg/cm) (30 visual fields were observed, and no peeled sites were recognized)
“NG”: peeled at a linear pressure of 1.0 times (600 kg/cm) (30 visual fields were observed, and one or more peeled sites were recognized)

As shown in Table 2, the laminated resin films of Examples 1 to 21 had a low electric resistance of 3 μΩ·m or less. In addition, the laminated resin films of Examples 1 to 21 had a sufficient fracture elongation of 4.5% or more. Furthermore, in the laminated resin films of Examples 1 to 21, the calendering resistance treatment was evaluated as “no peeling” or “extremely good”, meaning that the Cu film 3b was less likely to be peeled off from the resin layer 3a.

On the other hand, as shown in Table 2, in the laminated resin films of Comparative Examples 1 and 2 in which the orientation index of the (111) plane of the Cu film 3b according to the Lotgering method was less than 0.15, the calendering resistance treatment was evaluated as “NG”.

### Reference Signs List

3, 33, 35 Laminated resin film
3a Resin layer
3b Cu film
3c Underlayer
10 Separator
20 Positive electrode
22 Positive electrode current collector
24 Positive electrode active material layer
30 Negative electrode
32 Negative electrode current collector
34 Negative electrode active material layer
40 Power generating part
50 Exterior body
62 Lead
100 Lithium secondary battery

1. A laminated resin film comprising:
a resin layer; and
a Cu film provided on one surface or both surfaces of the resin layer,
wherein in the Cu film, an orientation index of a (111) plane is 0.15 or more according to a Lotgering method, a half-width of an X-ray diffraction peak obtained by X-ray diffraction measurement of the (111) plane is 0.3° or less, and Expression (1) is satisfied,
y≥3.75x−0.675 Expression (1)
(in Expression (1), Y is the orientation index of the (111) plane in the Cu film according to the Lotgering method, and x is the half-width of the X-ray diffraction peak obtained by the X-ray diffraction measurement of the (111) plane in the Cu film).

2. The laminated resin film according to claim 1, wherein the orientation index of the Cu film is 0.3 to 0.98.

3. The laminated resin film according to claim 1, wherein the half-width of the X-ray diffraction peak of the Cu film is 0.08° to 0.26°.

4. The laminated resin film according to claim 1, wherein a thickness of the Cu film is 0.3 μm to 2.0 μm.

5. The laminated resin film according to claim 1, wherein an underlayer is provided between the resin layer and the Cu film so as to be in contact with the resin layer and the Cu film.

6. A current collector comprising the laminated resin film according to claim 1.

7. A secondary battery comprising:
a negative electrode;
a positive electrode facing the negative electrode; and
a separator positioned between the negative electrode and the positive electrode,
wherein any one or both of the negative electrode and the positive electrode have the current collector according to claim 6.
